(19) United States
(12) Patent Application Publication
(10) Pub. No.: US 2026/0150669 A1
(43) Pub. Date: May 28, 2026

(54) INTEGRATED POWER MODULE WITH ENHANCED HEAT MANAGEMENT

(71) Applicant: Monolithic Power Systems, Inc., Kirkland, WA (US)

(72) Inventors: Kwang-Soo Kim, Sunnyvale, CA (US); Di Han, San Jose, CA (US)

(21) Appl. No.: 18/958,395

(22) Filed: Nov. 25, 2024

(51) Int. Cl. H01L 23/367; H01L 23/00; H01L 23/13; H01L 23/498; H01L 25/18

(52) U.S. Cl. CPC H10W 40/226; H10W 70/65; H10W 70/68; H10W 90/00; H10W 72/884; H10W 90/734; H10W 90/753; H10W 90/754; H10W 90/756

(57) ABSTRACT

Power devices, controllers and other components needed for a power delivery stage can be integrated in a small compact package to meet the larger and larger current capacities. However, significant amounts of heat generating by these power devices during operation may be conducted to the nearby controllers through the substrate and cause undesired thermal shutdown. By providing a substrate which includes a thermal conductive base plate with carefully designed recess, the heat can be properly directed and conducted through the substrate.

### TECHNICAL FIELD

Embodiments of the present invention relate to an integrated power module, and more particularly relate to a substrate for mounting components of the integrated power module.

### BACKGROUND OF THE INVENTION

Integrated power module can meet the larger and larger current capacities in a small compact package for server/network and automotive applications by integrating different kinds of components needed for a power delivery stage: power devices, controllers and passive components. All these components are mounted on a same substrate through careful design considering functional characteristics of the circuit, track pitch, heat dissipation and weights.

Power devices, such as SIC MOSFET/JFET, GaN FET, Si IGBT, Si MOSFET, Si SJ MOSFET etc., are switches of a power circuit. These power devices generate significant amounts of heat during operation, which must be properly directed and dissipated. Controllers are subsystems that are responsible for managing the power devices'actions and maintaining output voltage and current within desired levels. These controllers, which are usually Si ICs distributed closely next to the power devices, are very sensitive to high temperature resulting from heat aggregation.

When the controllers reach their thermal shutdown limit temperature, protective measures of the controllers will be taken to prevent overheating and potential damage, ensuring the safety and reliability of the power module. Hower, if the heat management of the substrate could be improved, the controllers will be less likely to reach their thermal shutdown limit temperature, as a result, the power module could have more efficient performance.

### SUMMARY OF THE INVENTION

Embodiments of the present invention are directed to a substrate for a power module. The substrate includes a thermal conductive base plate and a layer of dielectric material. The thermal conductive base plate includes a first side and a second side opposite to the first side. The layer of dielectric material is arranged on the first side of the thermal conductive base plate. A first region of the substrate is configured to carry power devices of the power module and a second region of the substrate is configured to carry controllers of the power module. A third region of the substrate is unpopulated with electronic devices and is situated between the first region and the second region. The thermal conductive base plate includes a first recess, the position of which corresponds to the position of the third region of the substrate.

Embodiments of the present invention are directed to a substrate for an integrated power module. The integrated power module includes a substrate. The substrate includes a thermal conductive base plate and a layer of dielectric material. The thermal conductive base plate includes a first side and a second side opposite to the first side. The layer of dielectric material is arranged on the first side of the thermal conductive base plate. At least some power devices of the power module are arranged on a first region of the substrate and at least one controller of the power module is arranged on a second region of the substrate. A third region of the substrate is unpopulated with electronic devices and is situated between the first region and the second region. The thermal conductive base plate includes a first recess, the position of which corresponds to the position of the third region of the substrate.

### BRIEF DESCRIPTION OF DRAWINGS

For a better understanding of the invention, embodiments of the invention will be described in accordance with the following drawings, which are used for illustrative purpose only. The drawings illustrate only some of the features in an embodiment. It should be understood that the drawings are not necessarily to scale. Like elements are provided with like reference numerals in different appended drawings.

FIG. 1 is a schematic view of a power module 100 in accordance with an example embodiment of the present disclosure.

FIG. 2A and FIG. 2B are a plan view and a side view of the power module 100 in accordance with an example embodiment of the present disclosure.

FIG. 3A and FIG. 3B are a side view and a plan view of a power module 200 in accordance with an example embodiment of the present disclosure.

FIG. 4A and FIG. 4B are a side view and a plan view of a power module 300 in accordance with an example embodiment of the present disclosure. FIG. 4C is an alternative embodiment of FIG. 4B.

FIG. 5A is a side view of a power module 400 in accordance with an example embodiment of the present disclosure. FIG. 5B is a side view of a power module 500 in accordance with an example embodiment of the present disclosure.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of this application described herein will be apparent. Description of materials and methods that are known in the art may not be addressed in this disclosure for simplicity.

Throughout the specification and claims, the articles “a,” “an,” and “the” are intended to include the plural forms as well, unless the context clearly indicates otherwise. These phases “one embodiment”, “an embodiment”, “an example” and “examples” are not necessarily directed to the same embodiment or example. Furthermore, the features, structures, or characteristics may be combined in one or more embodiments or examples. Throughout the specification and claims, the ordinal numbers “first,” “second,” and “third” are intended to indicate different features and are not intended to indicate the order. For example, “a second conductive net” is a conductive net different from the “a first conductive net”.

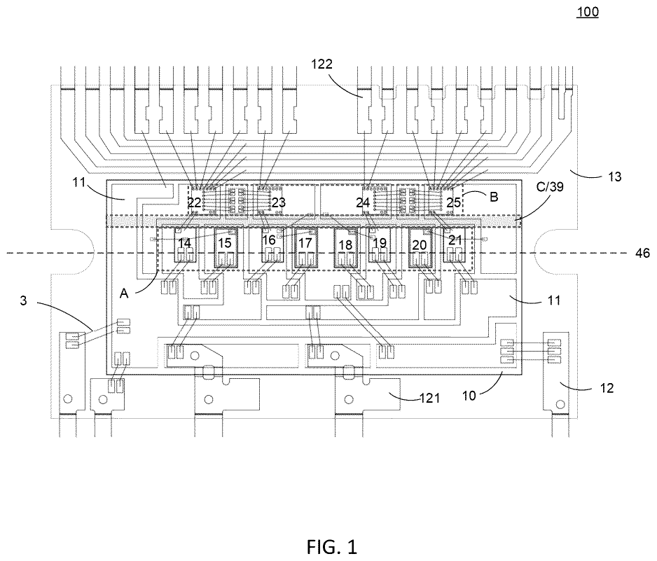

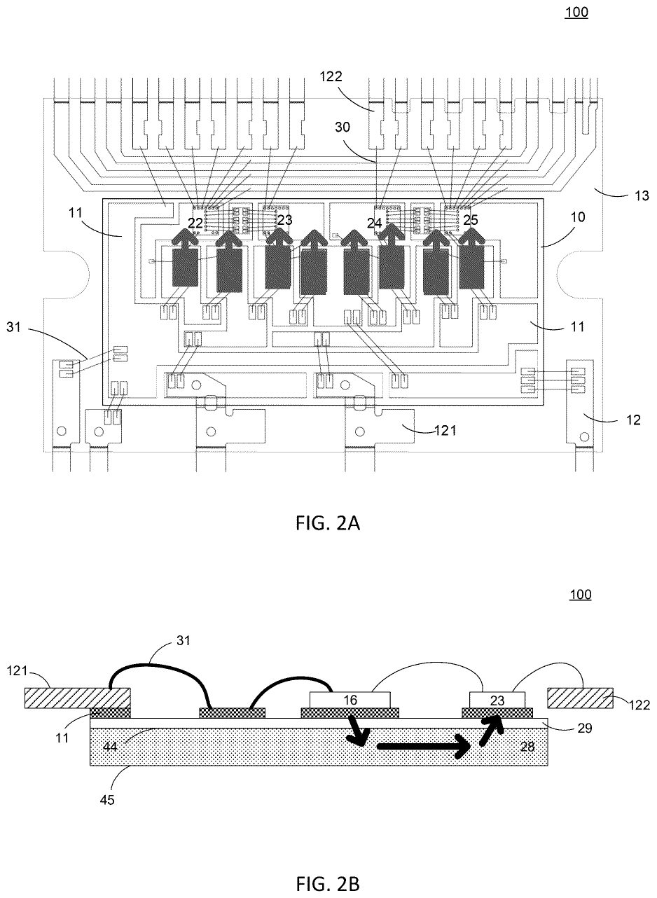

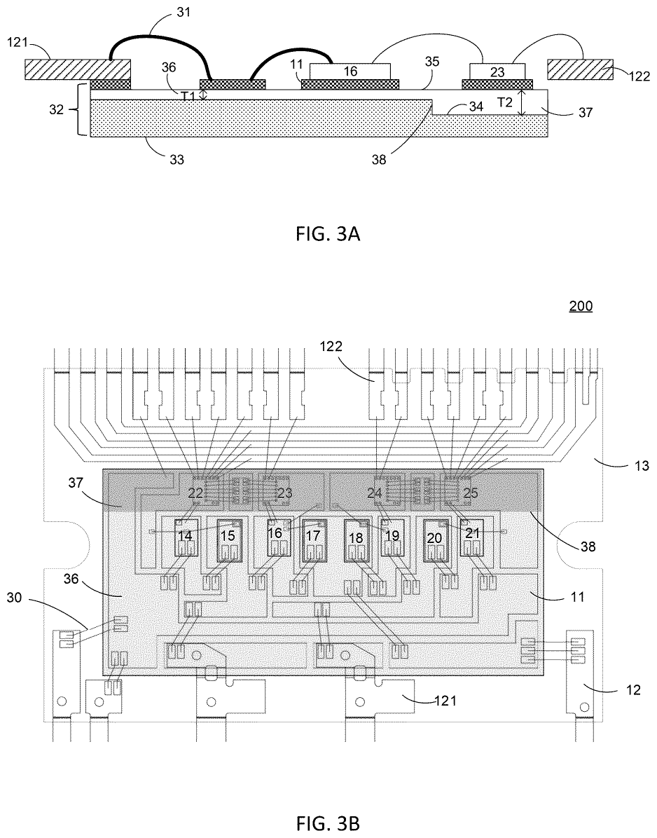

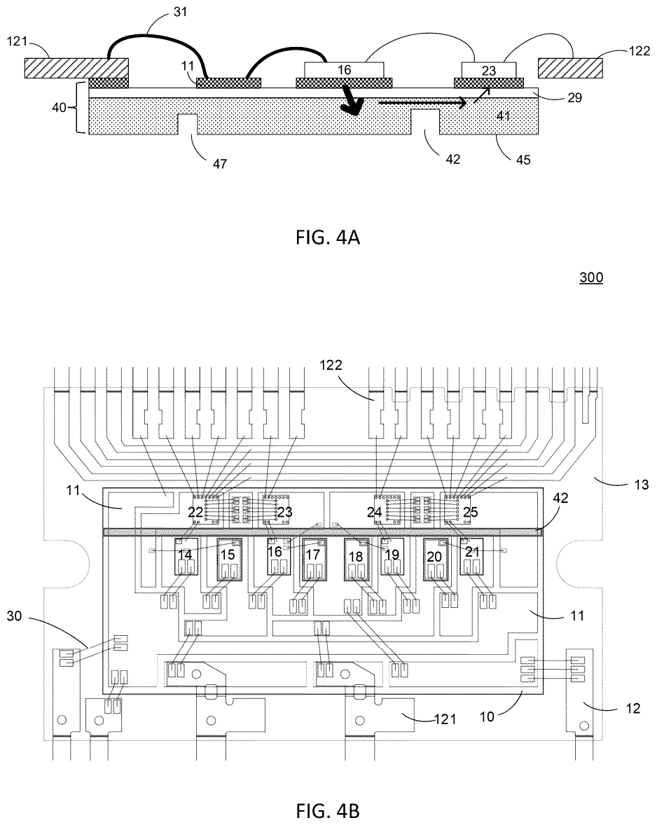

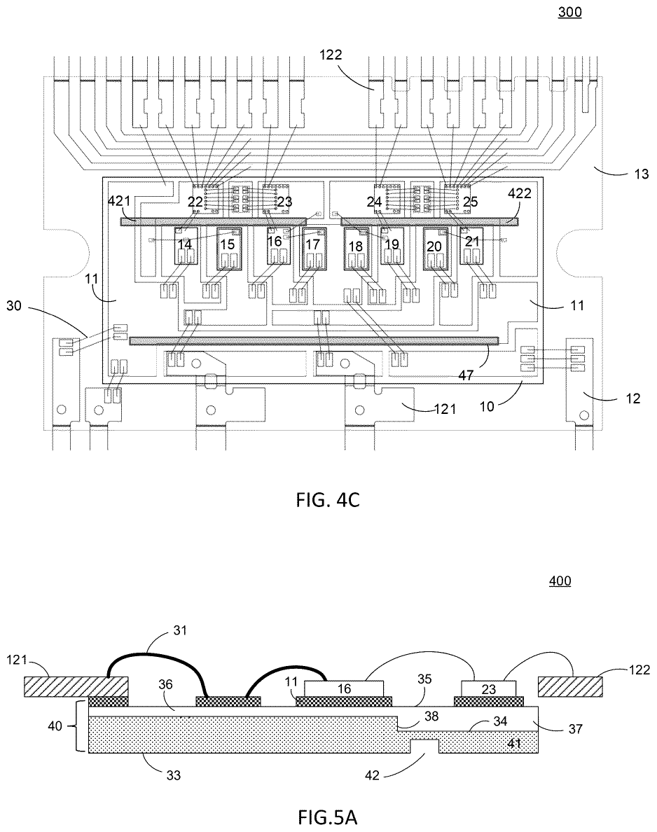

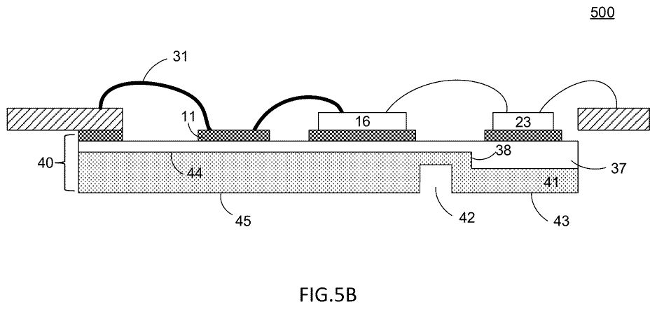

Exemplary power modules are illustrated in figures according to some embodiments of this disclosure. FIG. 1 is a schematic view of a power module 100. FIG. 2A and FIG. 2B are a plan view and a side view of the power module 100. FIG. 3A and FIG. 3B are a side view and a plan view of a power module 200. FIG. 4A and FIG. 4B are a side view and a plan view of a power module 300. FIG. 5A and FIG. 5B are a side views of a power module 400 and a power module 500. The following description collectively references each of FIGS. 1, 2 3 4 and 5.

Referring to FIG. 1 and FIG. 2B, a substrate 10 of the power module 100 includes a thermal conductive base plate 28 of copper, aluminum, or the like that provides mechanical structure and high thermal conductivity. The thermal conductive base plate 28 has a first side 44 and a second side 45 opposite to the first side 44. The substrate 10 further includes a patterned metallization layer 11 consists of several traces or pads of the following materials: copper, aluminum, gold or any suitable alloys. Components needed for the power module 100: power devices 14˜21, controllers 22˜25 and other suitable electronic devices are attached to the patterned metallization layer 11 at their predetermined mounting locations by solder materials (not shown in the figures) or the like. In some embodiments, a layer of dielectric material 29 capable of providing isolation between all the components and the thermal conductive base plate 28 is arranged between the patterned metallization layer 11 and the first side 44 of the thermal conductive base plate 28, covering the whole area of the first side 44 of the thermal conductive base plate 28.

Bond wires 30 are used for providing electrical interconnections between components, lead fingers 121 and 122 and the patterned metallization layer 11. As illustrated in FIG. 2B, larger diameter bond wires 31 are used between power device 16 and lead fingers 121 for providing relatively high current electrical interconnection. In this disclosure, as shown in FIG. 2B, FIG. 3A, FIG. 4A and FIG. 5A, the power devices 14˜21 and the controllers 22˜25 are carried by the same thermal conductive base plate 28 rather than two separate thermal conductive base plates. This design allows for reduced assembly difficulties. By bonding lead fingers 121 to the patterned metallization layer 11 by solder materials (not shown in the figures) or the like, without the need to bond lead fingers 122 to the substrate 32 through solder materials or the like, sufficiently support for the substrate 32 can be achieved. Referring to FIG. 2A, a housing 13 made of molding compound encapsulates all the components of the power module 100, providing mechanical structure, CTE matching and high voltage isolation. One end of each lead finger 121 and 122 protrudes out from the housing 13 to provide contacts for electrical connection from the outside.

Many factors need to be considered when spreading out the components on the substrate 10. For example, components having similar characteristics may be arranged symmetrically with respect to the substrate or to the housing, so that the heat dissipation and the weight distribution are symmetrical which may improve reliability of the power module 100. Besides, reducing the total length of bond wires and avoiding overlapping and intercrossing of bond wires could reduce resistance. The substrate 10 may include a first region A which is configured to carry the power devices 14˜21. As an example, in FIG. 1, the power devices 14˜21 are roughly distributed on the horizontal axis 46 of the exemplary power module 100, which is drawn longitudinally through the midline of the housing 13. The substrate 10 may include a second region B which is configured to carry the controllers 22˜25 and a third region C which is unpopulated with electronic devices and situated between the first region A and the second region B. As an example, in FIG. 1, the controllers 22˜25 are arranged on one side of the power devices 14˜21, leaving a narrow passage 39 of the substrate 32 unpopulated. In other embodiments, there may be some other power devices and some other controllers of the power module, which are not shown in these exemplary figures.

Reference is now made to FIG. 2A and FIG. 2B. Each of the power devices 14˜21 is a heat-generating center, which could likely cause the maximum junction temperature between the power devices and the patterned metallization layer 11 to rise up to 150° C. Most heat is dissipated through the metal base plate 28 which may be further attached to a heat sink or a system case, so that the heat could be ultimately released into the environment. However, the heat could also conduct along a path shown in FIG. 2B from the power devices 14˜21 to the nearby controllers 22˜25 through the metal base plate 28, causing undesired increase of the maximum junction temperature between the controllers 22˜25 and the patterned metallization layer 11. In an example, the maximum junction temperature between the controllers 22˜25 and the patterned metallization layer 11 may be raised to 87° C.

FIG. 3A and FIG. 3B are a side view and a plan view of a power module 200. A substrate 32 of the power module 200 includes a thermal conductive base plate 33 with a recess 34 which is designed to accommodate a layer of dielectric material 35 of varying thicknesses. The layer of dielectric material 35 features a stepped design, having a first section 36 of a first thickness T1 and a second section 37 of a thickness T2 that is greater than the thickness T1 of the first section 36, at the same time maintaining a flat top surface across the layer. However, in other embodiments, a flat surface is not necessary for the dielectric material layer 35. In an example shown in FIG. 3B, by comparing with FIG. 1, the position of the recess 34 corresponds to the position of the third region C of the substrate 32. That is to say, in the corresponding position of the first region A, the thermal conductive base plate includes a first topside region of a flat surface, while in the corresponding position of the third region C, there is a second topside region recessed or sunken relative to the surface of the first topside region. In some embodiments, the second topside region of recessed or sunken surface may be arranged corresponds the whole area of the third region C and the second region B. A connection of the first section 36 and the second section 37 is a step feature 38. The step feature 38 could interrupt the heat conduction path shown in FIG. 2B, making the heat conduction from power devices to the controllers less straightforward. In an example shown in FIG. 3B, by comparing with FIG. 1, it can be seen that the second section 37 of the layer of dielectric material 35 is configured below the first region A where the controllers 22˜25 are arranged. The first section 36 of the layer of dielectric material is configured below the second region B where the power devices 14˜21 are arranged. The step feature 38 is configured below the third region C where the unpopulated passage 39 is.

FIG. 4A and FIG. 4B are a side view and a plan view of a power module 300. A substrate 40 of the power module 300 includes a recess 42 which opens from the second side 45 of the thermal conductive base plate 41. The layer of dielectric material 29 having an uniform thickness is arranged at the first side 44 of the thermal conductive base plate 41, covering the whole area of the first side 44 of the thermal conductive base plate 41. The recess 42 makes specific section of the base plate 41 become thin, and thus increase the thermal resistance of the heat conduction path shown in FIG. 2B, making this heat conduction path less effective. The position of the recess 42 corresponds to the position of the third region C of the substrate. In an example shown in FIG. 4B, by comparing with FIG. 1, it can be seen that the recess 42 could be a full-line slot 42 configured below the third region C where the unpopulated passage 39 is. In other embodiments, as shown in FIG. 4C, the recess 42 could include two separate slots 421 and 422 which are configured below the third region C. In some embodiments of this disclosure, a third recess 47, which opens from the second side 45 of the thermal conductive base plate 41, is designed to mitigate substrate warpage. Its position corresponds to that of the second recess 42. In an example, the third recess 47 and the second recess 42 are arranged roughly symmetrically with respect to the substrate 40.

FIG. 5A and FIG. 5B are side views of a power module 400 and a power module 500. In these embodiments, the thermal conductive base plate 41 includes a first recess 34 which opens from the first side 44 and a second recess 42 which opens from the second side 45. The dielectric material layer 35 having a first section 36 of a first thickness T1 and a second section 37 of a thickness T2 that is greater than the first thickness T1 could be accommodated with the first side 44 just right, all while maintaining a flat top surface across the layer. However, in other embodiments, a flat surface is not necessary for the layer of dielectric material 35. A connection of the first section 36 and the second section 37 is a step feature 38. The step feature 38 could be arranged below the third region C, closer to the first region A than the second region B as shown in FIG. 5A or closer to the second region B than the first region A as shown in FIG. 5B. In example shown in FIG. 5A, the second recess 42 is arranged below the third region C and below the second section 37 of the dielectric material layer 35, while in the example shown in FIG. 5B, the second recess 42 is arranged below the third region C and below the first section 36 of the dielectric material layer 35. By arranging the first recess 34 and the second recess 42 on the thermal conductive base plate 41, heat conducting from the first region A to the second region B could be magnificently reduced.

While some embodiments of the present invention have been described in detail above, it should be understood, of course, these embodiments are for exemplary illustration only and are not intended to limit the scope of the present invention. Various modifications are contemplated, and they obviously will be resorted to by those skilled in the art without departing from the spirit and the scope of the invention.

1. A substrate for a power module, comprising:
a thermal conductive base plate of a substrate, the thermal conductive base plate includes a first side and a second side opposite to the first side;
a layer of dielectric material of the substrate, arranged on the first side of the thermal conductive base plate;
a first region of the substrate, configured to carry power devices of the power module;
a second region of the substrate, configured to carry controllers of the power module;
a third region of the substrate, unpopulated with electronic devices, wherein the third region is situated between the first region and the second region; and wherein
the thermal conductive base plate includes a first recess, the position of which corresponds to the position of the third region of the substrate.

2. The substrate of claim 1, wherein the first recess opens from the first side of the thermal conductive base plate.

3. The substrate of claim 2, wherein the layer of dielectric material includes a first section of a first thickness and a second section of a second thickness which is greater than the first thickness, and wherein the layer of dielectric material is accommodated with the first side.

4. The substrate of claim 2, wherein the layer of dielectric material includes a step feature which is accommodated by the first recess, wherein the step feature is configured below the third region.

5. The substrate of claim 2, wherein the thermal conductive base plate further includes a second recess which opens from the second side of the thermal conductive base plate, wherein the second recess is configured below the third region.

6. The substrate of claim 5, wherein the thermal conductive base plate further includes a third recess which opens from the second side of the thermal conductive base plate, wherein its position corresponds to that of the first recess and that of the second recess.

7. The substrate of claim 1, wherein the first recess opens from the second side of the thermal conductive base plate and is configured below the third region.

8. The substrate of claim 7, wherein the thermal conductive base plate further includes a third recess which opens from the second side of the thermal conductive base plate, wherein its position corresponds to that of the first recess.

9. An integrated power module, comprising:
a thermal conductive base plate of a substrate, the thermal conductive base plate includes a first side and a second side opposite to the first side;
a layer of dielectric material of the substrate, arranged on the first side of the thermal conductive base plate;
at least some power devices of the power module, arranged on a first region of the substrate;
at least one controller of the power module, arranged on a second region of the substrate;
a third region of the substrate, unpopulated with electronic devices, wherein the third region is situated between the first region and the second region; and wherein
the thermal conductive base plate includes a first recess, the position of which corresponds to the position of the third region of the substrate.

10. The integrated power module of claim 9, the power devices and the at least one controller are carried by the same thermal conductive base plate.

11. The integrated power module of claim 9, further comprising:
a first set of lead fingers, arranged around a first side of the substrate and closer to the power devices than the at least one controller;
a second set of lead fingers, arranged around a second side of the substrate and closer to the at least one controller than the power devices, wherein the second side is opposite to the first side of the substrate;
the first set of lead fingers, bonded to the substrate by solder materials;
the second set of lead fingers, not bonded to the substrate by solder materials.

12. The integrated power module of claim 9, wherein the first recess opens from the first side of the thermal conductive base plate.

13. The integrated power module of claim 12, wherein the layer of dielectric material includes a first section of a first thickness and a second section of a second thickness which is greater than the first thickness, and wherein the layer of dielectric material is accommodated with the first side.

14. The integrated power module of claim 12, wherein the layer of dielectric material includes a step feature which is accommodated by the first recess, wherein the step feature is configured below the third region.

15. The integrated power module of claim 12, wherein the thermal conductive base plate further includes a second recess which opens from the second side of the thermal conductive base plate, wherein the second recess is configured below the third region.

16. The integrated power module of claim 15, wherein the thermal conductive base plate further includes a third recess which opens from the second side of the thermal conductive base plate, wherein its position corresponds to that of the first recess and that of the second recess.

17. The integrated power module of claim 9, wherein the first recess opens from the second side of the thermal conductive base plate and is configured below the third region.

18. The integrated power module of claim 17, wherein the thermal conductive base plate further includes a third recess which opens from the second side of the thermal conductive base plate, wherein its position corresponds to that of the first recess.
